(19) United States
(12) Patent Application Publication
(10) Pub. No.: US 2011/0115036 A1
(43) Pub. Date: May 19, 2011

(54) DEVICE PACKAGES AND METHODS OF FABRICATING THE SAME

(75) Inventors: Jong Tae MOON, Chungcheongnam-do (KR); Jong-Hyun Lee, Gyeonggi-do (KR); Dong Suk Jun, Daejeon (KR); Hyun-cheol Bae, Daejeon (KR); Sunghae Jung, Daejeon (KR); Moo Jung Chu, Daejeon (KR)

(73) Assignee: ELECTRONICS AND TELECOMMUNICATIONS RESEARCH INSTITUTE, Daejeon (KR)

(21) Appl. No.: 12/768,551

(22) Filed: Apr. 27, 2010

(30) Foreign Application Priority Data
Nov. 18, 2009 (KR) 10-2009-0111462

(51) Int. Cl. H01L 29/84; H01L 21/60; H01L 23/488

(52) U.S. Cl. 257/415; 438/124; 257/E21.506; 257/E29.324; 257/E23.023

(57) ABSTRACT

Provided is a method for fabricating a device package. The method includes: preparing a substrate where respectively corresponding device structures and input and output pads are disposed on an active surface; preparing a carrier substrate where a metal lid corresponding to the device structure is disposed on one surface; and contacting the active surface of the substrate with the metal lid of the carrier substrate to cover and seal the device structure corresponding to the metal lid.

### CROSS-REFERENCE TO RELATED APPLICATIONS

This U.S. non-provisional patent application claims priority under 35 U.S.C. §119 of Korean Patent Application No. 10-2009-0111462, filed on Nov. 18, 2009, the entire contents of which are hereby incorporated by reference.

### BACKGROUND OF THE INVENTION

The present invention disclosed herein relates to a package including Micro Electro Mechanical Systems (MEMS) or sensor devices and a method of fabricating the same, and more particularly, to a package including MEMS or sensor devices sealed by a micro-sized lid and a method of fabricating the same.

In general, since devices with a MEMS (such as a Radio Frequency (RF) filter, an RF switch, an actuator, a Film Bulk Acoustic Resonator (FBAR), an accelerometer, or a gyroscope), which is manufactured by a chip unit) or a sensor device structure for performing specific functions, which is manufactured by a chip unit, are vulnerable to influences (such as moisture, particles, or high temperature) of physical or chemical external environments, additional packaging is required. This packaging is achieved by covering an upper surface of a substrate (where a device structure for performing a specific function is manufactured) with a lid having a predetermined cavity (which provides a space for accommodating the device structure) and then performing hermetic sealing on the covered upper surface of the substrate.

A Wafer Level Package (WLP) refers to a plurality of device packages, which is completed by sealing each of a plurality of device structures corresponding to a plurality of packaging lids (which are manufactured by a wafer unit) before a wafer having the plurality of device structures is cut by a chip unit. This WLP technology is appropriate for device mass production.

In relation to the WLP technology appropriate for device mass production, in order to protect MEMS or sensor device structures, after a cavity and a rim structure for joining are formed on a substrate such as silicon or glass through a typical semiconductor fabricating processes with several steps, a wiring connection to the external and a sealing process are performed by attaching the above substrate to a substrate including MEMS or sensor device structures.

However, the cost for a packaging substrate attached to a substrate including MEMS or sensor device structures accounts for about 50% of the cost for fabricating a device package. That is, it is relatively expensive. Moreover, since the packaging substrate itself is used, it is very difficult to reduce the thickness of a lid less than about 100 μm realistically.

### SUMMARY OF THE INVENTION

The present invention provides a device package including MEMS or sensor structures, which can reduce a manufacturing cost and can be miniaturized.

The present invention also provides a method of fabricating a device package including MEMS or sensor structures, which can reduce a manufacturing cost and can be miniaturized.

Embodiments of the present invention provide devices package including: a device structure on an active surface of a substrate; an input pad and an output pad on the active surface of the substrate; and a metal lid having an inner space to cover and seal the device structure on the active surface of the substrate.

In some embodiments, the device packages may further include a joining pattern interposed between the active surface of the substrate and the metal lid.

In other embodiments, the joining pattern may include a non-conductive adhesive material, and the input and output pads are interposed between the joining pattern and the active surface of the substrate.

In still other embodiments, the input and output pads may be interposed to cross a portion of the metal lid.

In even other embodiments, the joining pattern may include a conductive adhesive material, the input and output pads may be interposed between the joining pattern and the active surface of the substrate, and the device package may further include a non-conductive adhesive material layer interposed between portions where the joining pattern and the input and output pads overlap.

In yet other embodiments, the conductive adhesive material may include a middle melting point intermetallic compound.

In further embodiments, the joining pattern may include a conductive adhesive material, and the input and output pads may be provided on the active surface of the substrate at the external of the metal lid.

In still further embodiments, the device structure may include a device structure of Micro Electro Mechanical Systems (MEMS) or a sensor.

In even further embodiments, the device packages may further include: a wiring substrate having a mounting surface on which a device including the device structure and the metal lid is mounted; and bonding wires connecting the input and output pads of the device with the wiring substrate electrically.

In yet further embodiments, the device packages may further include a molding portion to seal the device, the bonding wires, and the mounting surface of the wiring substrate.

In other embodiments of the present invention, methods for fabricating a device package include: preparing a substrate where respectively corresponding device structures and input and output pads are disposed on an active surface; preparing a carrier substrate where a metal lid corresponding to the device structure is disposed on one surface; and contacting the active surface of the substrate with the metal lid of the carrier substrate to cover and seal the device structure corresponding to the metal lid.

In some embodiments, preparing the substrate may include: forming an adhesion layer on the one surface of the carrier substrate; forming a plurality of cap portions of the metal lid on the adhesion layer; and forming a rim portion at an edge of the cap portion.

In other embodiments, forming the cap portion and the rim portion may be performed through an electroplating method.

In still other embodiments, the methods may further include, before contacting the active surface of the substrate with the metal lid of the carrier substrate, forming a joining pattern on at least one surface of the active surface of the substrate and a surface of the rim portion of the metal lid that contacts the active surface.

In even other embodiments, the joining pattern may be formed of a non-conductive adhesive material, and the input and output pads may be interposed between the joining pattern and the active surface of the substrate.

In yet other embodiments, the joining pattern may be formed of a conductive adhesive material, the input and output pads may be interposed between the junction pattern and the active surface of the substrate, and the method further may include forming a non-conductive adhesive material layer on a portion where the junction pattern and the input and output pads overlap.

In further embodiments, the conductive adhesive material may be formed of a middle melting point intermetallic compound that is a chemical reaction result of a first melting point metal layer on the active surface of the substrate and a second melting point metal layer on the surface of the metal lid, the second melting point metal layer being different from the first melting point metal layer.

In still further embodiments, the methods may further include: forming Under Bump Metallurgy (UBM) interposed between the active surface of the substrate and the first melting point metal layer.

In even further embodiments, the joining pattern may be formed of a conductive adhesive material, and the input and output pads may be disposed on the active surface of the substrate at the external of the metal lid.

In yet further embodiments, the methods may further include, after contacting the active surface of the substrate with the metal lid of the carrier substrate, removing the carrier substrate.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1A is a plan view illustrating a device package according to an embodiment of the present invention;

FIGS. 1B and 1C are sectional views taken along the line I-I′ and the line II-II′ of FIG. 1A, respectively;

FIG. 2 is a plan view illustrating a device package according to another embodiment of the present invention;

FIGS. 3 through 10 are fabricating sectional views illustrating a fabricating method of a device package according to an embodiment of the present invention;

FIGS. 11 and 12 are views illustrating an additional fabricating method of a device package according to an embodiment of the present invention;

FIG. 13 is a plan view illustrating a device package according to another embodiment of the present invention; and

FIGS. 14 through 16 are fabricating sectional views taken along the line III-III′ of FIG. 13 to illustrate a fabricating method of a device package according to another embodiment of the present invention.

### DETAILED DESCRIPTION OF PREFERRED EMBODIMENTS

Preferred embodiments of the present invention will be described below in more detail with reference to the accompanying drawings. Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Like reference numerals refer to like elements throughout.

In the following description, the technical terms are used only for explaining a specific exemplary embodiment while not limiting the present invention. The terms of a singular form may include plural forms unless referred to the contrary. The meaning of ‘comprises’ and/or ‘comprising’ specifies a property, a region, a fixed number, a step, a process, an element and/or a component but does not exclude other properties, regions, fixed numbers, steps, processes, elements and/or components. Since preferred embodiments are provided below, the order of the reference numerals given in the description is not limited thereto. In the specification, it will be understood that when a layer (or film) is referred to as being ‘on’ another layer or substrate, it can be directly on the other layer or substrate, or intervening layers may also be present.

Additionally, the embodiment in the detailed description will be described with sectional views as ideal exemplary views of the present invention. In the figures, the dimensions of layers and regions are exaggerated for clarity of illustration. Accordingly, shapes of the exemplary views may be modified according to fabricating techniques and/or allowable errors. Therefore, the embodiments of the present invention are not limited to the specific shape illustrated in the exemplary views, but may include other shapes that may be created according to fabricating processes. For example, an etched region illustrated as a rectangle may have rounded or curved features. Areas exemplified in the drawings have general properties, and are used to illustrate a specific shape of a semiconductor package region. Thus, this should not be construed as limited to the scope of the present invention.

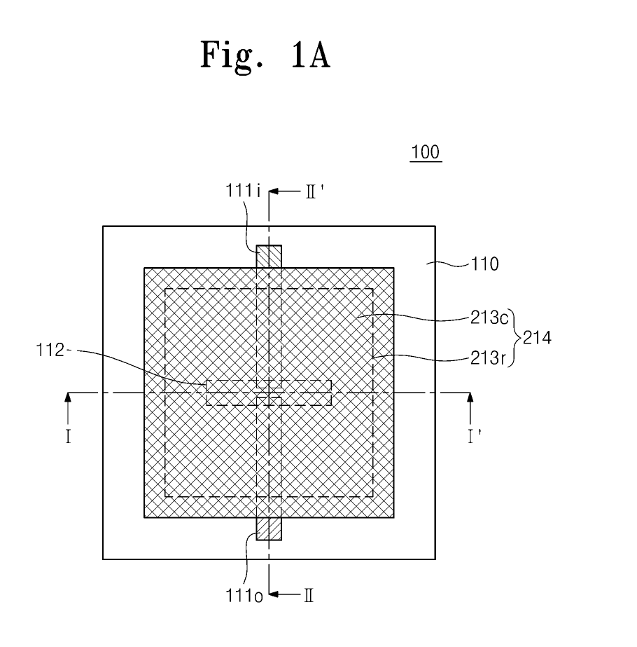

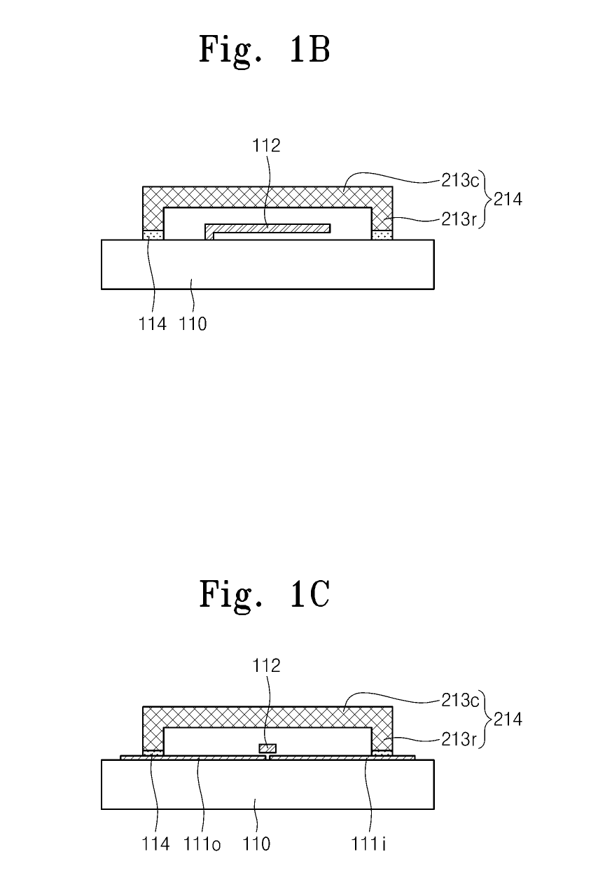

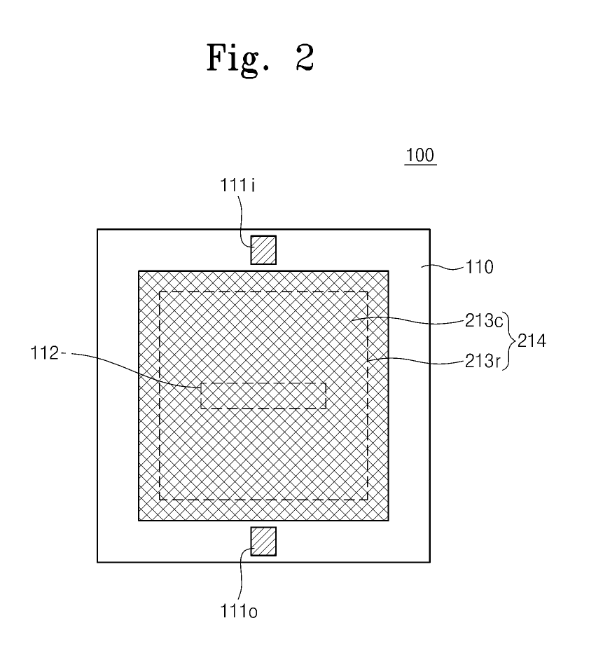

FIG. 1A is a plan view illustrating a device package according to an embodiment of the present invention. FIGS. 1B and 1C are sectional views taken along the line I-I′ and the line II-II′ of FIG. 1A, respectively. Additionally, FIG. 2 is a plan view illustrating a device package according to another embodiment of the present invention.

Referring to FIGS. 1A through 1C, a device 100 of a device package includes a substrate 110, a device structure 112, input/output pads 111i and 111o and a metal lid 214.

The substrate 110 may be a semiconductor substrate. The semiconductor substrate may be a silicon wafer.

The device structure 112 and the input/output pads 111i and 111o may be disposed on an active surface of the substrate 110. The device structure 112 and the input/output pads 111i and 111o may be formed on an active surface of the substrate 110 through a general fabricating process. The device structure 112 may be a Micro Electro Mechanical Systems (MEMS) device structure or a sensor device structure. The input/output pads 111i and 111o input a signal into the device structure 112 and output a signal from the device structure 112.

The metal lid 214 may be disposed on the active surface of the substrate 110 to cover and seal the device structure 112. The metal lid 214 may include a metal material such as Ni and Cu. Besides the metal lid 214, a lid including an inorganic material may be used. The metal lid 214 may include an inner space for covering and sealing the device structure 112. The inner space of the metal lid 214 is provided by a cap portion 213c and a rim portion 213r at the edge of the cap portion 213c constituting the metal lid 214. The surface of the rim portion 213r of the metal lid 214 contacts the active surface of the substrate 110, such that the metal lid 214 can cover and seal the device structure 112. Accordingly, the device structure 112 may provide more accurate measurement value since it is protected from physical or chemical external environments.

In general, the device structure 112 has a height of less than several μm such that the metal lid 214 can have a height of about 10 μm. Accordingly, the metal lid 214 can obtain sufficient space that protects the device structure 112 from physical or chemical external environments. That is, the metal lid 214 can drastically reduce the height of a device package compared to a typical package substrate having a thickness of several hundreds μm.

It may further include a joining pattern 114 interposed between the active surface of the substrate 110 and the metal lid 214. The joining pattern 114 may enhance joining intensity between the active surface of the substrate 110 and the surface of the rim portion 213r of the metal lid 214. The joining pattern 114 may have the same form as the rim portion 213r of the metal lid 214 and thus may be entirely interposed between the metal lid 214 and the active surface of the substrate 110.

The joining pattern 114 may include a non-conductive adhesive material. The non-conductive adhesive material may include polymer resin adhesive. When the joining pattern 114 includes a non-conductive adhesive material, as shown in FIG.1C, the input/output pads 111i and 111o are interposed between the joining pattern 114 and the active surface of the substrate 110. Accordingly, the input/output pads 111i and 111o may be interposed to cross the rim portion 213r of the metal lid 214.

Referring to FIG. 2, the joining pattern 114 may include a conductive adhesive material. The conductive adhesive may include a middle melting point intermetallic compound. The middle melting point intermetallic compound may include CuIn. When the joining pattern 114 includes a conductive adhesive material, the input/output pads 111i and 111o may be disposed on the active surface of the substrate 110 outside the metal lid 214.

This configuration of the respectively different input/output pads 111i and 111o in FIGS. 1A and 2 may prevent a short circuit phenomenon, which is caused because the input/output pads 111i and 111o are not separated due to a physical contact between the metal lid 214 and the input/output pads 111i and 111o and are electrically connected to each other.

Although the joining pattern 114 is entirely interposed between the metal lid 214 and the active surface of the substrate 110 in FIGS. 1A through 2, the joining pattern 114 may be interposed only between portions where the input/output pads 111i and 111o and the metal lid 214 overlap.

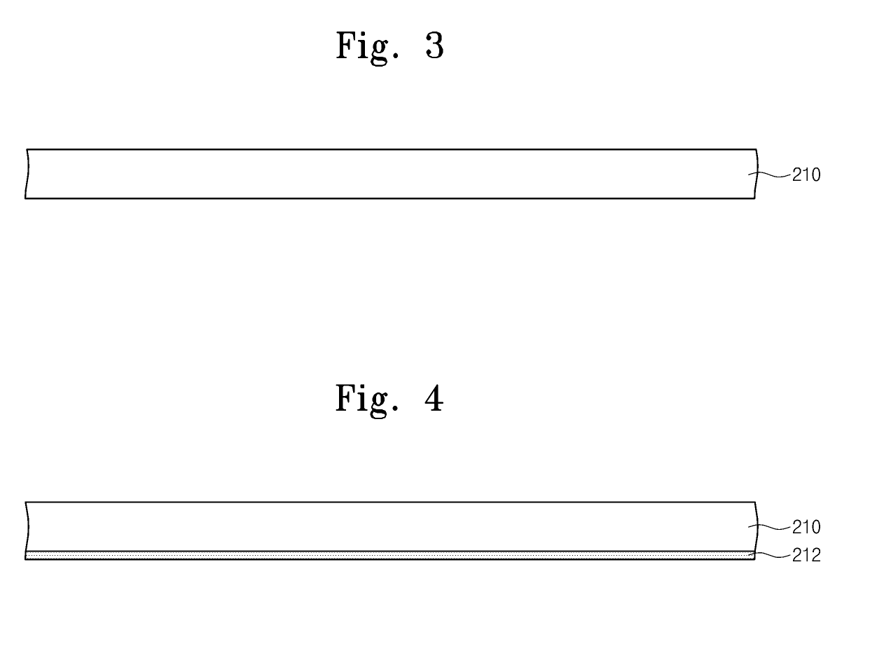

FIGS. 3 through 10 are fabricating sectional views illustrating a fabricating method of a device package according to an embodiment of the present invention.

Referring to FIGS. 3 and 4, a carrier substrate 210 is prepared. The carrier substrate 210 may be a wafer including silicon, glass, metal, or ceramic.

An adhesion layer 212 is formed on one surface of the carrier substrate 210. The adhesion layer 212 may be formed of a low temperature solder layer or a polymer resin layer. This is for removing the carrier substrate 210 without difficulties after the metal lids 214 are attached to the active surface of the substrate 110.

The low temperature solder layer may be formed through physical sputter, a thermal deposition process, or a chemical plating process. If necessary, the low temperature solder layer is formed by depositing Under Bump Metallurgy (UBM), i.e., an adhesion layer and a solder layer and then forming a conductive adhesive material. The low temperature solder layer used as the adhesion layer 212 may include a pure metal such as In or Sn, or an In, Sn, Bi or Pb base compound. If the low temperature solder layer is used as the adhesion layer 212, since the adhesion layer 212 has a joining characteristic at a low temperature, the metal lid 214 can be attached to the carrier substrate 210. Since the adhesion layer 212 has a melting characteristic at a high temperature, the carrier substrate 210 can be detached.

A polymer resin layer may be formed through various coating methods such as spin coating or spray coating. The polymer resin layer may use a reworkable adhesive that can be detached without difficulties after attachment. The reworkable adhesive may use an adhesive including an Ultraviolet curable resin (UV resin) or a thermoplastic resin. If an adhesive including a thermoplastic resin is used as the adhesion layer 212, since the adhesion layer 212 has a joining characteristic at a low temperature, the metal lid 214 can be attached to the carrier substrate 210. Since the adhesion layer 212 has a flowing characteristic at a high temperature, the carrier substrate 210 can be detached.

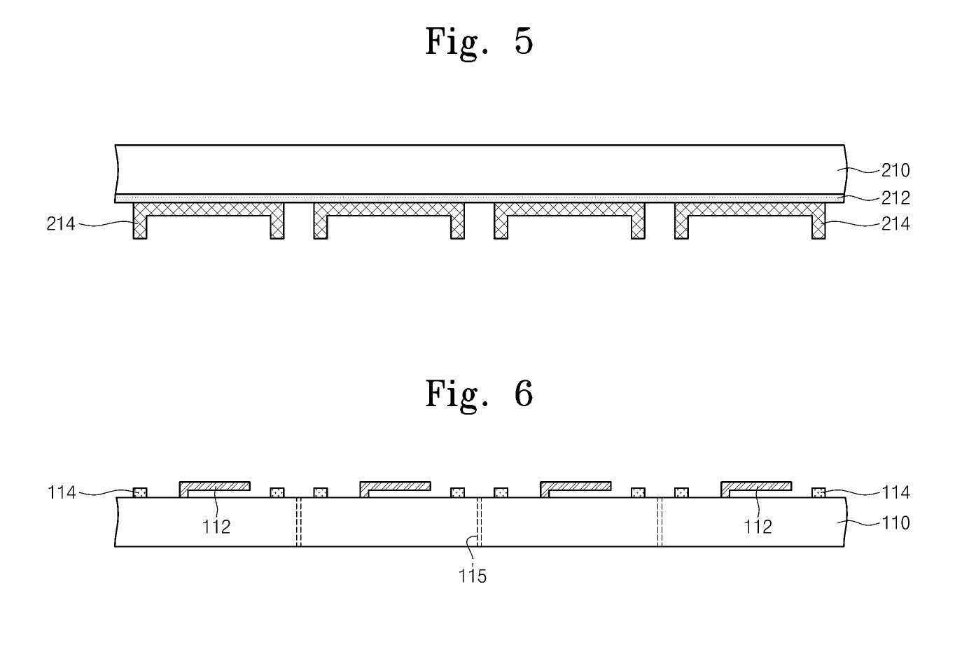

Referring to FIG. 5, a plurality of metal lids 214 are formed on the carrier substrate 210 having the adhesion layer 212. The metal lid 214 may include a metal material such as Ni and Cu.

The forming of the metal lids 214 may include forming a plurality of cap portions on the adhesion layer 212 and forming rim portions at an edge of each of the cap portions. The forming of the cap portion and rim portion for each metal lid 214 may be accomplished through an electroplating method.

If the adhesion layer 212 is a low temperature solder layer, a first photoresist is coated on the entire surface of the adhesion layer 212 and then regions of the first photoresist where the metal lids 214 will be formed is removed through a photolithography process. Then, cap portions of the metal lids 214 are formed through a first plating process, and then a second photoresist is coated on the entire surface of the result having the cap portions, and then a second photoresist at the edge of each cap portion is removed through a photolithography process. Next, rim portions of the metal lids 214 are formed through a second plating process and then the first and second photoresists are removed. Therefore, the metal lid 214 having an inner space surrounded by each cap portion and rim portion is formed. Unlike this, a rim portion may be formed at the edge of the cap portion by directly etching the middle region of the cap portion formed through the first plating process.

In addition, when the adhesion layer 212 is a polymer resin layer, a metal layer is formed on the entire surface of the adhesion layer 212 through lamination joining, and then the metal lids 214 having an inner space surrounded by each cap portion and rim portion is formed through a method similar to the above photolithography process using a photoresist. Unlike this, the metal lid 214 may be formed by directly etching a metal layer formed through lamination joining.

Referring to FIG. 6, prepared is a substrate 110 where a plurality of device structures 112 are disposed on the active surface. The substrate 110 may include scribe lines 115 such that it can be divided into each device 100 of FIG. 1A in a later process. Input/output pads 111i and 111o of FIG. 1A corresponding to the device structure 112 may be further provided on the active surface of the substrate 110 including the device structures 112 that is divided by the scribe lines 115.

The metal lids 214 on the carrier substrate 210 are formed to have the same arrangement as the device structures 112 of FIG. 6 on the substrate 110.

Joining patterns 114 corresponding to each surface of the rim portions of the metal lids 214 are formed on the active surface of the substrate 110. Unlike this, the joining patterns 114 may be formed on each surface of the rim portions of the metal lids 214 contacting the active surface of the substrate 110.

The joining pattern 114 may include a non-conductive adhesive material. The non-conductive adhesive material may include a polymer resin adhesive. The joining pattern 114 may include a conductive adhesive material. The conductive adhesive material may include a middle melting point intermetallic compound. The middle melting point intermetallic compound may include CuIn. When the joining pattern 114 includes a conductive adhesive material, non-conductive adhesive material layers may be further included between portions where the joining pattern 114 and the input/output pads overlap.

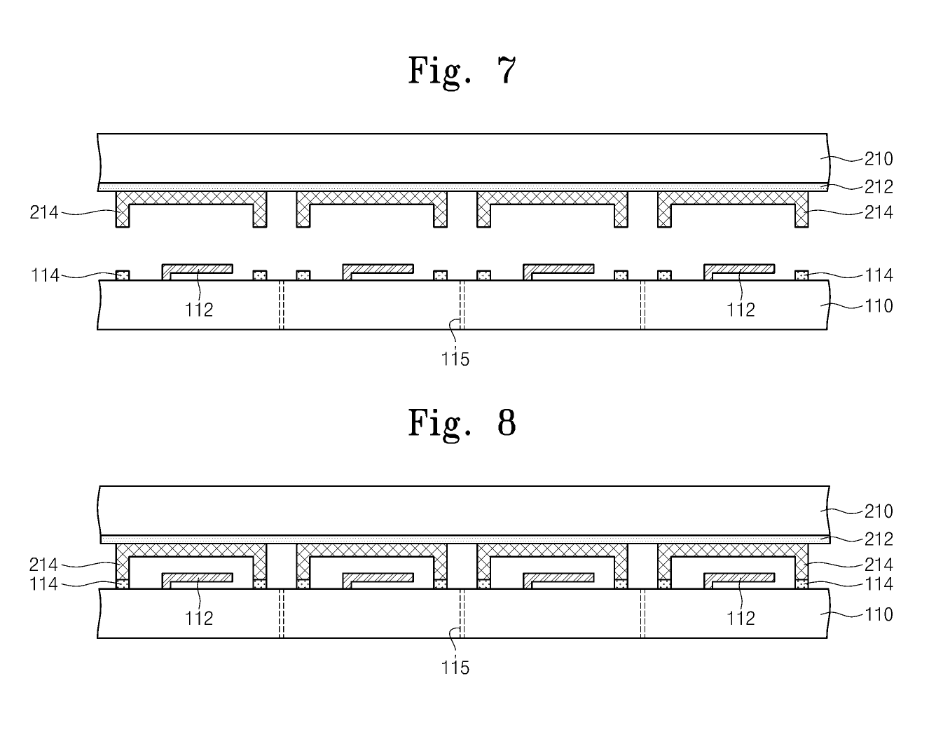

Referring to FIGS. 7 and 8, the active surface of the substrate 110 contacts the metal lid 214 of the carrier substrate 210 in order to cover and seal the device structures 112 corresponding to the metal lids 214. The active surface of the substrate 110 may contact the metal lid 214 of the carrier substrate 210 in vacuum equipment. The active surface of the substrate 110 may contact the metal lid 214 of the carrier substrate 210 using applied heat in vacuum equipment.

The active surface of the substrate 110 may contact the metal lid 214 of the carrier substrate 210 through the joining patterns 114. When the joining pattern 114 includes a non-conductive adhesive material, the metal lid 214 may be attached to the active surface of the substrate 110 by the adhesiveness of the joining pattern 114, and when the joining pattern 114 includes a conductive adhesive material, the metal lid 214 may be attached to the active surface of the substrate 110 by the adhesiveness of an intermetallic compound that is the result of a chemical reaction between metal layers of respectively different more than two kinds.

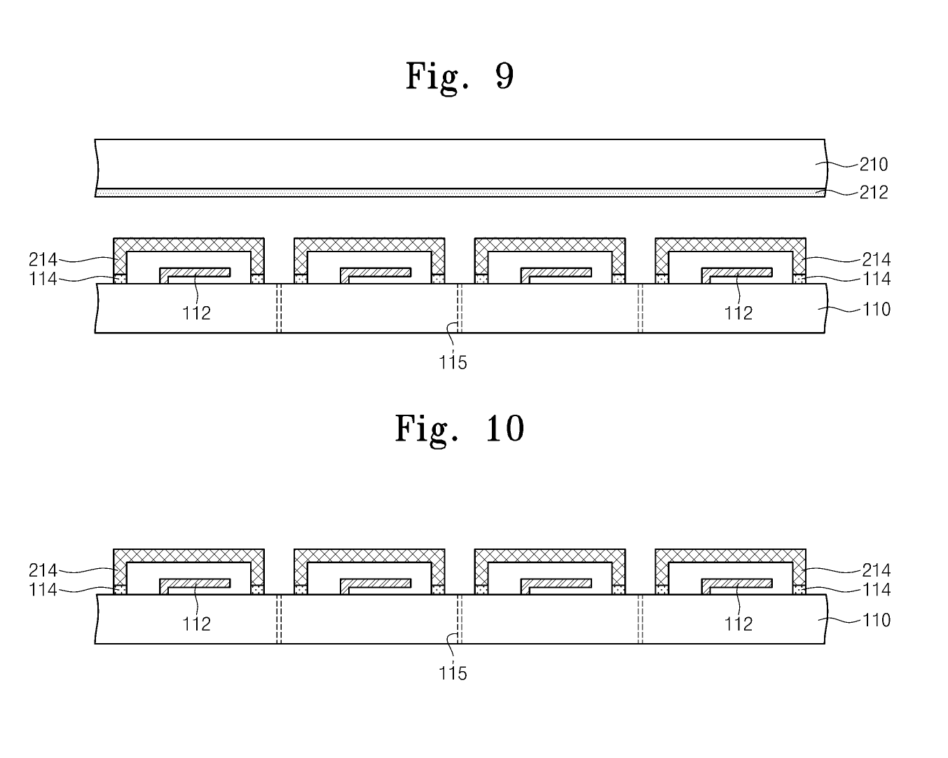

Referring to FIGS. 9 and 10, the carrier substrate 210 including the adhesion layer 212 is removed. Since the adhesion layer 212 is formed of a low temperature solder layer or a polymer resin layer, the carrier substrate 210 is removed without difficulties after the metal lids 214 is attached to the active surface of the substrate 110. A heat may be applied to the adhesion layer 212 to remove the carrier substrate 210 with the adhesion layer 212.

When the low temperature solder layer is used as the adhesion layer 212, since the adhesion layer 212 has a melting characteristic at a high temperature, the carrier substrate 210 can be detached. When the low temperature solder layer between the carrier substrate 210 and the metal lids 214 changes into a liquid state by a heat, the carrier substrate 210 may be detached without difficulties by applying a relatively small sheer stress that exceeds the surface tension of the liquid low temperature solder layer.

When an adhesive including a thermoplastic resin is used as the adhesion layer 212, since the adhesion layer 212 has a flowing characteristic at a high temperature, the carrier substrate 210 can be detached. When the thermoplastic resin between the carrier substrate 210 and the metal lids 214 has a flowing characteristic due to a heat, since the adhesion layer 212 is detached based on the inner of the adhesion layer 212 where flowing occurs easily by shear stress, the carrier substrate 210 can be detached without difficulties.

After the carrier substrate 210 including the adhesion layer 212 is removed, the substrate 110, which has the device structures 112 are covered and sealed by the corresponding metal lids 214, is cut along the scribe lines 115. The cutting of the substrate 110 along the scribe lines 115 may be accomplished using various equipments such as diamond sawing equipment or laser beam equipment. Accordingly, the substrate 110 is divided into each device with the device structure 112 covered and sealed by the metal lid 214.

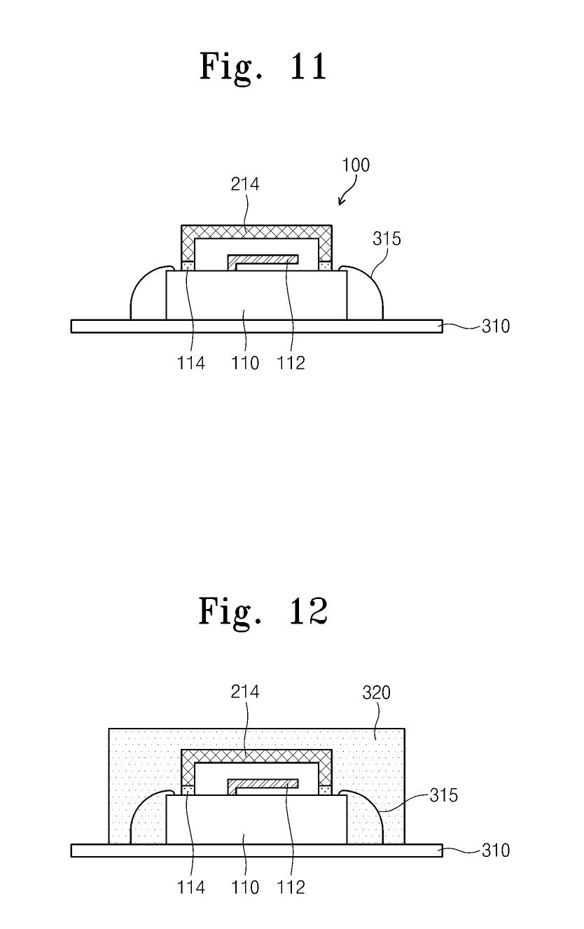

FIGS. 11 and 12 are views illustrating an additional fabricating method of a device package according to an embodiment of the present invention. A device having a section taken along the line I-I′ of FIG. 1A is shown.

Referring to FIGS. 11 and 12, the separated one device is mounted on a mounting surface of a wiring substrate 310. The wiring substrate 310 may be a Printed Circuit Board (PCB). The device 100 may be mounted on the mounting surface of the wiring substrate 310 using an adhesive material layer (not shown) as medium.

Bonding wires 315 are formed to electrically connect the input/output pads 111i and 111o of the FIG. 1A of the device 100 with the wiring substrate 310. The bonding wires 315 may be an Au wire. Accordingly, the device structure 112 in the device 100 and the wiring substrate 310 may be electrically connected to each other.

A molding portion 320 is formed to seal the device 100, the bonding wires 315, and the mounting surface of the wiring substrate 310. The molding portion 320 may include Epoxy Molding Compound (EMC). The molding portion 320 may be formed by a transfer molding method. The molding portion 320 may improve low sealing characteristic that can occur when the joining pattern 114 attaching the metal lid 214 to the active surface of the substrate 110 is formed of a polymer resin adhesive. The molding portion 320 may be formed after peripheral regions including the joining pattern 114 is enhanced with coating of a special material, in order to greatly improve sealing characteristics against moisture penetration.

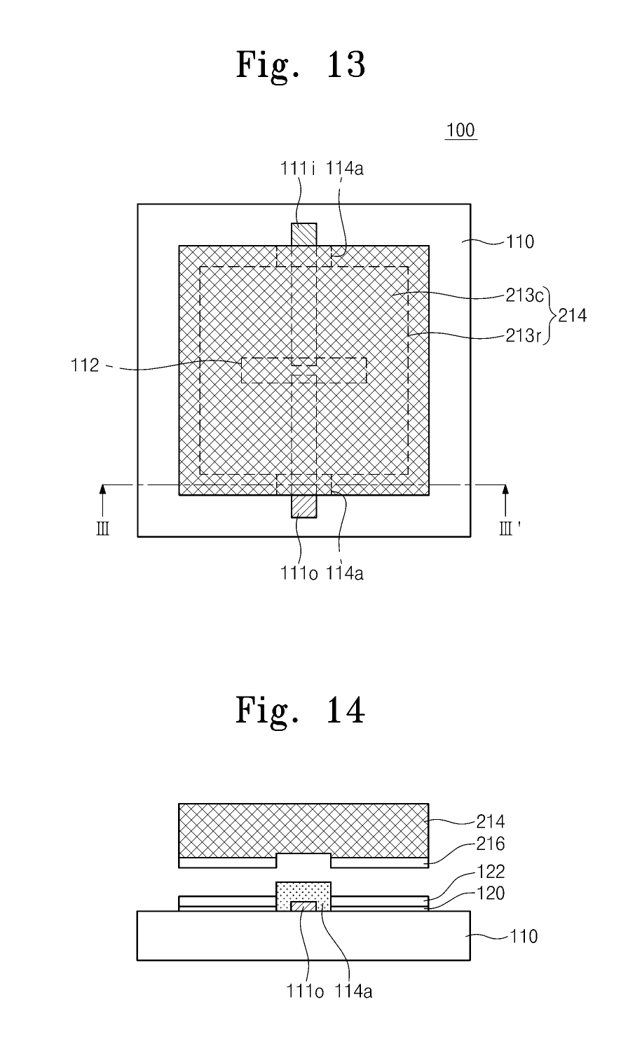

FIG. 13 is a plan view illustrating a device package according to another embodiment of the present invention. FIGS. 14 through 16 are fabricating sectional views taken along the line III-III′ of FIG. 13 to illustrate a fabricating method of a device package according to another embodiment of the present invention.

Referring to FIGS. 13 and 14, non-conductive adhesive material layers 114 are formed to cover portions of the input/output pads 111i and 111o on the active surface of the substrate 110 that overlaps the metal lid 214. The non-conductive adhesive material layers 114 may prevent a short circuit phenomenon, which is caused because the input/output pads 111i and 111o are not separated due to a physical contact between the metal lid 214 and the input/output pads 111i and 111o and are electrically connected to each other.

Except for portions where the non-conductive adhesive material layers 114 is formed, an Under Bump Metallurgy (UBM) 120 is formed on the active surface of the substrate 110 corresponding to the rim portion 213r of the metal lid 214. Next, a high melting point metal layer 122 is formed on the UBM 120. The high melting point metal layer 122 may include a metal layer of more than one kind. The high melting point metal layer 122 may include Cu. The UBM 120 is used to form the high melting point metal layer 122 without difficulties.

Except for the portions of the rim portion 213r that overlap the input/output pads 111i and 111o, a low melting point metal layer 216 is formed on the surface of the rim portion 213r of the metal lid 214 corresponding to the high melting point metal layer 122. The low meting point metal layer 216 may include a metal layer of more than one kind. The low melting point metal layer 216 may include In.

Here, the high melting point metal layer 122 and the low melting point metal layer 216 are interchangeable. That is, the low melting point metal layer 216 is formed on the UBM 120 and the high melting point metal layer 22 may be formed on the surface of the rim portion 213r of the metal lid 214. At this point, as mentioned above, when the metal lid 214 is formed of Cu, a process for forming the high melting point metal layer 122 on the surface of the rim portion 213r of the metal lid 214 can be omitted.

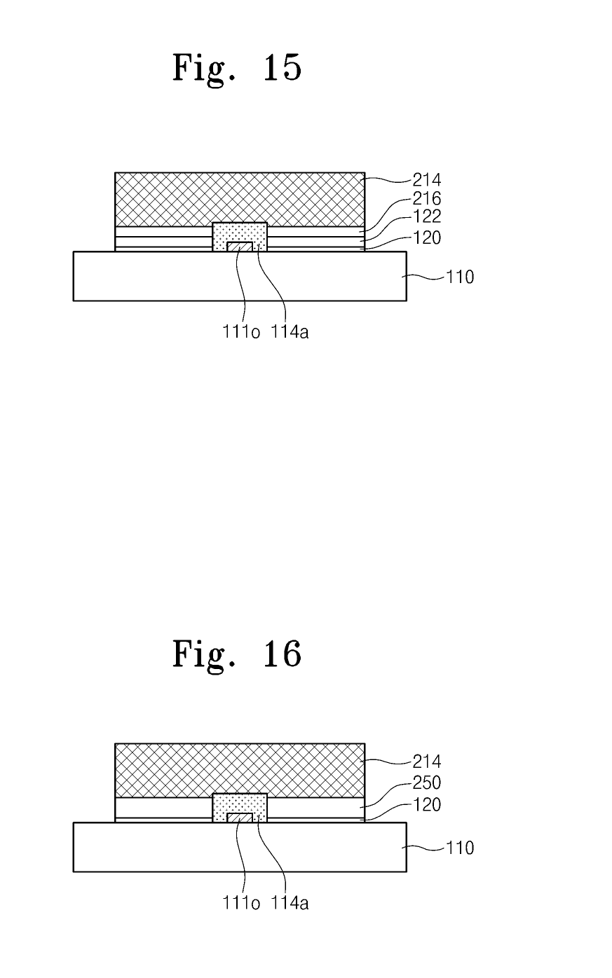

Referring to FIGS. 15 and 16, the high melting point metal layer 122 on the active surface of the substrate 110 contacts the low melting point metal layer 216 on the surface of the rim portion 213r of the metal lid 214. Next, by applying a heat with a higher temperature at which the low melting point metal layer 216 is melted, the high melting point metal layer 22 and the low melting point metal layer 215 react to form the middle melting point intermetallic compound layer 250. The formed middle melting point intermetallic compound layer 250 may include CuIn. Accordingly, the active surface of the substrate 110 and the metal lid 214 may be attached to each other by the middle melting point intermetallic compound layer 250.

The device packages according to the embodiments of the present invention include MEMS and sensor device structures covered and sealed by a micro-sized metal lid, and thus have a very smaller lid having a height of less than 10 μm compared to a typical lid having a height of several hundreds μm using a package substrate. Accordingly, a miniaturized device package can be provided. Additionally, since the lid is formed of a metal material, fabricating coast can be reduced. Accordingly, this device package can reduce a manufacturing cost.

Additionally, in relation to the fabricating methods according to the embodiments of the present invention, after a micro-sized metal lid is formed on a carrier substrate, the carrier substrate is attached to a substrate including MEMS or sensor device structures. Therefore, unlike typical semiconductor fabricating processes of several steps performed on a package substrate to form a lid, the lid of the present invention can be formed with a simple process for forming a metal pattern. Accordingly, the device package can be manufactured without difficulties. Furthermore, since the carrier substrate can be recyclable, manufacturing cost can be more reduced through the above fabricating method of the device package.

Moreover, since device packages according to embodiments of the present invention have MEMS or sensor device structures covered and sealed by a micro-sized metal lid, deterioration of sealing characteristics that may occur in a later process can be minimized. Accordingly, more accurate measurement value close to the design value of a device can be provided, and the device package can continuously maintain a desirable measurement characteristics.

As a result, the device packages according to embodiments of the present invention can maintain reliable sealing characteristics and ultimately contribute to reduction of the manufacturing cost and miniaturization of a package.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A device package comprising:
a device structure on an active surface of a substrate;
an input pad and an output pad on the active surface of the substrate; and
a metal lid having an inner space to cover and seal the device structure on the active surface of the substrate.

2. The device package of claim 1, further comprising a joining pattern interposed between the active surface of the substrate and the metal lid.

3. The device package of claim 2, wherein:
the joining pattern comprises a non-conductive adhesive material; and
the input and output pads are interposed between the joining pattern and the active surface of the substrate.

4. The device package of claim 3, wherein the input and output pads are interposed to cross a portion of the metal lid.

5. The device package of claim 2, wherein:
the joining pattern comprises a conductive adhesive material;
the input and output pads are interposed between the joining pattern and the active surface of the substrate; and
the device package further comprises a non-conductive adhesive material layer interposed between portions where the joining pattern and the input and output pads overlap.

6. The device package of claim 5, wherein the conductive adhesive material comprises a middle melting point intermetallic compound.

7. The device package of claim 2, wherein:
the joining pattern comprises a conductive adhesive material; and
the input and output pads are provided on the active surface of the substrate at the external of the metal lid.

8. The device package of claim 1, wherein the device structure comprises a device structure of Micro Electro Mechanical Systems (MEMS) or a sensor.

9. The device package of claim 1, further comprising:
a wiring substrate having a mounting surface on which a device including the device structure and the metal lid is mounted; and
bonding wires electrically connecting the input and output pads of the device with the wiring substrate.

10. The device package of claim 9, further comprising a molding portion to seal the device, the bonding wires, and the mounting surface of the wiring substrate.

11. A method for fabricating a device package, the method comprising:
preparing a substrate where respectively corresponding device structures and input and output pads are disposed on an active surface;
preparing a carrier substrate where a metal lid corresponding to the device structure is disposed on one surface; and
contacting the active surface of the substrate with the metal lid of the carrier substrate to cover and seal the device structure corresponding to the metal lid.

12. The method of claim 11, wherein preparing the substrate comprises:
forming an adhesion layer on the one surface of the carrier substrate;
forming a plurality of cap portions of the metal lid on the adhesion layer; and
forming a rim portion at an edge of the cap portion.

13. The method of claim 12, wherein forming the cap portion and the rim portion is performed through an electroplating method.

14. The method of claim 12, further comprising:
before contacting the active surface of the substrate with the metal lid of the carrier substrate, forming a joining pattern on at least one surface of the active surface of the substrate and a surface of the rim portion of the metal lid that contacts the active surface.

15. The method of claim 14, wherein:
the joining pattern is formed of a non-conductive adhesive material; and
the input and output pads are interposed between the joining pattern and the active surface of the substrate.

16. The method of claim 14, wherein:
the junction pattern is formed of a conductive adhesive material;
the input and output pads are interposed between the joining pattern and the active surface of the substrate; and
the method further comprises forming a non-conductive adhesive material layer on portions where the junction pattern and the input and output pads overlap.

17. The method of claim 16, wherein the conductive adhesive material is formed of a middle melting point intermetallic compound that is a chemical reaction result of a first melting point metal layer on the active surface of the substrate and a second melting point metal layer on the surface of the metal lid, the second melting point metal layer being different from the first melting point metal layer.

18. The method of claim 17, further comprising:
forming Under Bump Metallurgy (UBM) interposed between the active surface of the substrate and the first melting point metal layer.

19. The method of claim 14, wherein:
the joining pattern is formed of a conductive adhesive material; and
the input and output pads are disposed on the active surface of the substrate at the external of the metal lid.

20. The method of claim 11, further comprising:
after contacting the active surface of the substrate with the metal lid of the carrier substrate, removing the carrier substrate.
